(19) United States
(12) Patent Application Publication
(10) Pub. No.: US 2010/0197089 A1
(43) Pub. Date: Aug. 5, 2010

(54) METHODS OF FABRICATING SEMICONDUCTOR DEVICES WITH METAL-SEMICONDUCTOR COMPOUND SOURCE/DRAIN CONTACT REGIONS

(75) Inventors: Jin-Bum Kim, Seoul (KR); Yu-Gyun Shin, Seongnam-si (KR); Jung-Yun Won, Hwaseong-si (KR); In-Sun Jung, Suwon-si (KR); Jun-Ho Lee, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/699,491

(22) Filed: Feb. 3, 2010

(30) Foreign Application Priority Data
Feb. 5, 2009 (KR) 10-2009-0009378

(51) Int. Cl. H01L 21/8238

(52) U.S. Cl. 438/199; 257/E21.632

(57) ABSTRACT

Methods of fabricating semiconductor devices include forming a transistor on and/or in a semiconductor substrate, wherein the transistor includes a source/drain region and a gate pattern disposed on a channel region adjacent the source/drain region. An insulating layer is formed on the transistor and patterned to expose the source/drain region. A semiconductor source layer is formed on the exposed source/drain region and on an adjacent portion of the insulating layer. A metal source layer is formed on the semiconductor source layer. Annealing, is performed to form a first metal-semiconductor compound region on the source/drain region and a second metal-semiconductor compound region on the adjacent portion of the insulating layer. The first metal-semiconductor compound region may be thicker than the second metal-semiconductor compound region. The metal source layer may include a metal layer and a metal nitride barrier layer.

### CROSS-REFERENCE TO RELATED APPLICATION

This application claims the benefit of priority under 35 U.S.C. §119 from Korean Patent Application No. 10-2009-0009378, filed on Feb. 5, 2009. the contents of which are hereby incorporated herein by reference in its entirety.

### BACKGROUND

The inventive subject matter relates to methods of fabricating semiconductor devices and, more particularly, to methods of fabricating contact structures for semiconductor devices.

Semiconductor devices widely employ devices, such as MOS transistors, as switching devices. When the size of a MOS transistor is reduced, a channel resistance of the MOS transistor may be reduced, so that the MOS transistor may support a high drive current and switching rate. However, in smaller transistors, electrical resistance of contact regions may increase.

### SUMMARY

Some embodiments provide methods of fabricating semiconductor devices having metal-semiconductor compound regions.

According to some embodiments, methods of fabricating semiconductor devices include forming a transistor on and/or in a semiconductor substrate, wherein the transistor includes a source/drain region and a gate pattern disposed on a channel region adjacent the source/drain region. An insulating layer is formed on the transistor and patterned to expose the source/drain region. A semiconductor source layer is formed on the exposed source/drain region and on an adjacent portion of the insulating layer. A metal source layer is formed on the semiconductor source layer. Annealing is performed to form a first metal-semiconductor compound region on the source/drain region and a second metal-semiconductor compound region on the adjacent portion of the insulating layer. The first metal-semiconductor compound region may be thicker than the second metal-semiconductor compound region. The metal source layer may include a metal layer and a metal nitride barrier layer.

In some embodiments, the first metal-semiconductor compound region includes a semiconductor material from the semiconductor source layer, a semiconductor material from the source/drain region and a metal material from the metal source layer. and wherein the second metal-semiconductor compound region includes a semiconductor material from the first semiconductor source layer and the metal material from the metal source layer. In some embodiments, forming the semiconductor source layer is preceded by implanting a semiconductor material into the source/drain region and forming a buffer region on the implanted source/drain region. The first metal-semiconductor compound region may include a semiconductor material from the semiconductor source layer, a semiconductor material from the source/drain regions and the semiconductor material implanted into the buffer region. In further embodiments, forming the semiconductor source layer is preceded by forming a recess in the exposed source/drain region and forming the semiconductor source layer includes filling the recess with the semiconductor source layer.

In additional embodiments, forming the transistor includes forming spaced apart first and second transistors on and/or in the semiconductor substrate. wherein the first transistor includes a first source/drain region and a first gate pattern disposed on a first channel region adjacent the first source/drain region and wherein the second transistor includes a second source/drain region and a second gate pattern disposed on a second channel region adjacent the second source/drain region. Forming the insulating layer includes forming the insulating layer on the first and second transistors. Patterning the insulating layer includes patterning the insulating layer to expose the first source/drain region and the second source/drain region. Forming the semiconductor source layer includes forming a mask layer on the exposed second source/drain region, forming a first semiconductor source layer on the exposed first source/drain regions and on a first portion of the insulating layer adjacent the first source/drain region, removing the mask layer to expose the second source/drain region and forming a second semiconductor source layer on the exposed second source/drain region and on second portion of the insulating layer adjacent the second source/drain region. Annealing is performed to form the first metal-semiconductor compound region on the first source/drain region, the second metal-semiconductor compound region on the first adjacent portion of the insulating layer, a third metal-semiconductor compound region on the second source/drain region and a fourth metal-semiconductor compound region on the second adjacent portion of the insulating layer. The first and second source/drain regions may have different conductivity types, the first semiconductor source layer may include an amorphous structure having the same conductivity type as the first source/drain region, and the second semiconductor source layer may include an amorphous structure having the same conductivity type as the second source/drain region.

### BRIEF DESCRIPTION OF THE DRAWINGS

Some embodiments are described in further detail below with reference to the accompanying drawings. It should be understood that various aspects of the drawings may have been exaggerated for clarity:

FIG. 1 is a flowchart illustrating operations for fabricating a semiconductor device according to some embodiments of the inventive subject matter; and

FIGS. 2-9 are cross-sectional views illustrating operations for fabricating a semiconductor device according to some embodiments of the inventive subject matter.

### DETAILED DESCRIPTION

Some embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the inventive subject matter to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

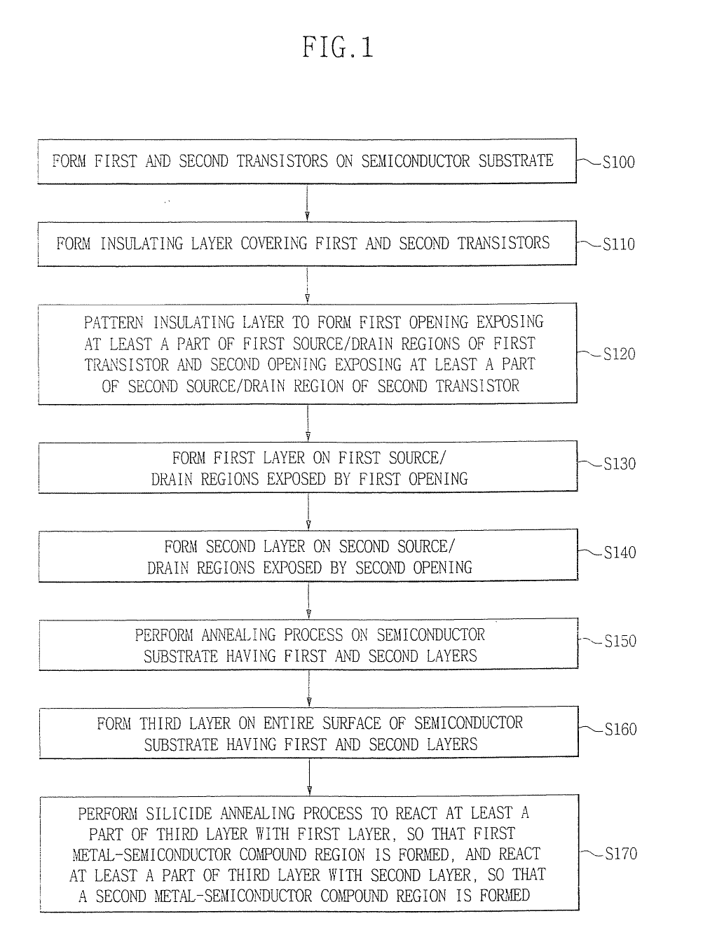

FIG. 1 is a flowchart illustrating operations for fabricating semiconductor devices according to some embodiments of the inventive subject matter, and FIGS. 1-9 are cross-sectional views illustrating operations for fabricating a semiconductor device according to some embodiments of the inventive subject matter. In FIGS. 1-9, a part represented by “A” denotes a first device region, and a part represented by “B” denotes a second device region.

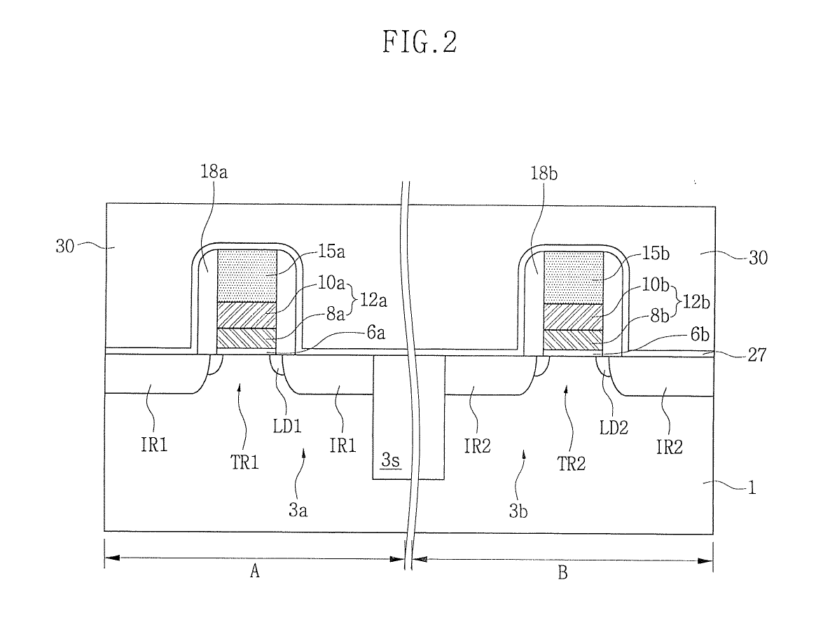

Referring to FIGS. 1 and 2, a semiconductor substrate 1 may be prepared. The semiconductor substrate 1 may be a wafer formed of a semiconductor material, such as silicon. An isolation region 3s defining first and second active regions 3a and 3b may be formed in the semiconductor substrate 1. The isolation region 3s may be formed using, for example, a trench isolation technique. For example, forming the isolation region 3s may include forming a trench region defining the first and second active regions 3a and 3b, and filling the trench region with an insulating material, such as a silicon oxide layer.

The first active region 3a may be defined in the first device region A of the semiconductor substrate 1, and the second active region 3b may be defined in the second device region B of the semiconductor substrate 1. The first active region 3a may have a first conductivity type, and the second active region 3b may have a second conductivity type. For example, a first well ion implantation process may be performed on the first active region 3a, so that the first active region 3a may have the first conductivity type, and a second well ion implantation process may be performed on the second active region 3b, so that the second active region 3b may have the second conductivity type. The first conductivity type may be a p-type, and the second conductivity type may be an n-type. In some embodiments, the first conductivity type may be an n-type, and the second conductivity type may be a p-type.

A first gate dielectric layer 6a, a first gate electrode 12a, and a first hard mask 15a, which are stacked, may be formed on the first active region 3a. A second gate dielectric layer 6b, a second gate electrode 12b, and a second hard mask 15b are stacked on the second active region 3b. The first gate electrode 12a may include a first lower conductive layer 8a, and a first upper conductive layer 10a, which are stacked. The first lower conductive layer 8a may be a doped polysilicon layer, and the first upper conductive layer 10a may be a conductive layer including at least one of a metal silicide layer and a metal layer. The second gate electrode 12b may include a second lower conductive layer 8b, and a second upper conductive layer 10b, which are stacked. The second lower conductive layer 8b may be a doped polysilicon layer, and the second upper conductive layer 10b may be a conductive layer including at least one of a metal silicide layer and a metal layer.

First lightly doped drain (LDD) regions LD1 may be formed in the first active region 3a at both sides of the first gate electrode 12a. Second LDD regions LD2 may be formed in the second active region 3b at both sides of the second gate electrode 12b. The first LDD regions LD1 may have a different conductivity type than the first active region 3a, and the second LDD regions LD2 may have a different conductivity type than the second active region 3b.

A spacer insulating layer may be formed on the surface of the semiconductor substrate having the first and second LDD regions LD1 and LD2, and then anisotropically etched. As a result, a first gate spacer 18a may be formed on sidewalls of the first gate electrode 12a and the first hard mask 15a, and a second gate spacer 18b may be formed on sidewalls of the second gate electrode 12b and the second hard mask 15b.

A first photoresist pattern (not shown) covering the second device region B and exposing the first device region A may be formed, and a first source/drain ion implantation process using the first photoresist pattern, the first hard mask 15a, the first gate spacer 18a and the isolation region 3s as ion implantation masks may be performed, so that first impurity regions IR1 may be formed in the first active region 3a, and the first photoresist pattern may be removed. A second photoresist pattern (not shown) covering the first device region A and exposing the second device region B may be formed, and a second ion implantation process using, the second photoresist pattern, the second hard mask 151), the second gate spacer 18b and the isolation pattern 3s as ion implantation masks may be performed, so that second impurity regions IR2 may be formed in the second active region 3b, and the second photoresist pattern may be removed.

Thus, a first transistor TR1 may be formed in the first device region A, and a second transistor TR2 may be formed in the second device region B (S100). In particular, the first transistor TRI may include the first gate dielectric layer 6a, the first gate electrode 12a, the first LDD regions LD1, the first impurity regions IR1, and a first channel region defined in the first active region 3a between the first impurity regions IR1. The second transistor TR2 may include the second gate dielectric layer 6b, the second gate electrode 12b, the second LDD regions LD2, the second impurity regions IR2, and a second channel region defined in the second active region 3b between the second impurity regions IR2.

Although a planar-type transistor is illustrated in the drawings and described, the present inventive subject matter it is not limited thereto. For example, the first and second transistors TR1 and TR2 may be 3-dimensional transistors, such as recessed channel transistors or Fin FETs.

An etch stop layer 27 may be formed on the surface of the semiconductor substrate having the first and second transistors IR1 and IR2. An interlayer insulating layer 30 may be formed on the etch stop layer 27 (S110). The interlayer insulating layer 30 may be an insulating material having an etch selectivity with respect to the etch stop layer 27. For example, when the etch stop layer 27 is formed of silicon nitride, the interlayer insulating, layer 30 may be formed of silicon oxide.

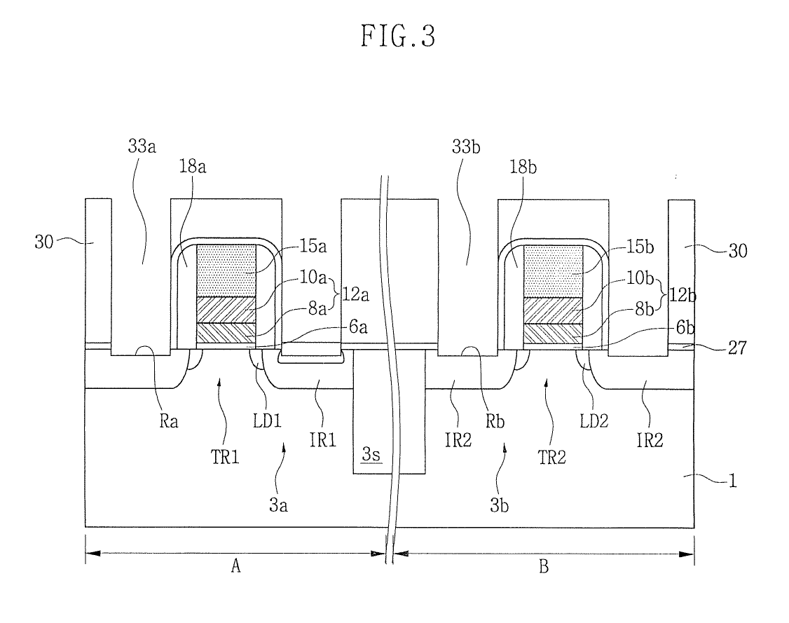

Referring to FIGS. 1 and 3, the interlayer insulating layer 30 may be patterned to form a first opening 33a exposing at least a part of the first impurity regions IR1 of the first transistor TR1, and form a second opening 33b exposing at least a part of the second impurity regions IR2 of the second transistor TR2 (S120).

The first and second impurity regions IR1 and IR2 exposed by the first and second openings 33a and 33b may be partially etched. Thus, first recesses Ra may be formed in the first impurity regions IR1, and second recesses Rb may be formed in the second impurity regions IR2.

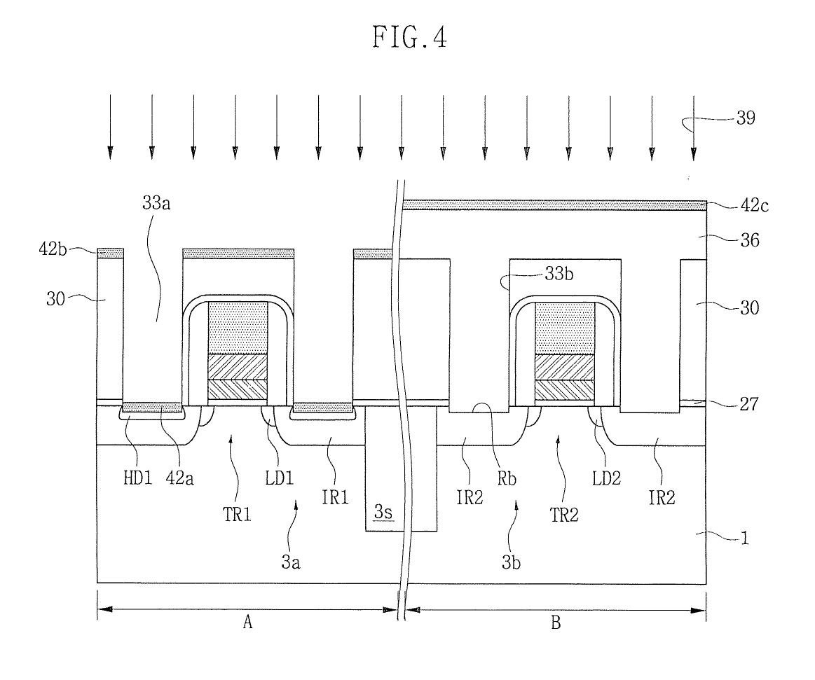

Referring to FIGS. 1 and 4, a first mask pattern 36 covering the semiconductor substrate of the second device region B, and exposing the semiconductor substrate of the first device region A may be formed. Thus, the first mask pattern 36 may expose the first openings 33a. The first mask pattern 36 may be a photoresist material.

A first vertical deposition process 39 may be performed on the semiconductor substrate having the first mask pattern 36, so that first layers 42a. 42b and 42c may be formed on the semiconductor substrate having, the first mask pattern 36 (S130). The first vertical deposition process may employ a beam line process. For example, the beam line process may be a gas cluster ion beam process in which a gas cluster ion beam is vertically irradiated to the semiconductor substrate. In some embodiments, the first vertical deposition process 39 may include generating, plasma in a process chamber into which the semiconductor substrate is loaded as a silicon source, and applying a bias to a wafer chuck where the semiconductor substrate is disposed in the process chamber such that silicon ions are vertically irradiated onto the semiconductor substrate from the plasma.

The first layers 42a, 42b and 42c may be doped using an in-situ doping process such that the first layers 42a, 42b and 42c have the same conductivity type as the first impurity regions IR1. In some embodiments, after the first layers 42a, 42b and 42c are formed of a first undoped amorphous layer, first impurity ions having the same conductivity type as the first impurity regions IR1 may be implanted into the first undoped amorphous layer.

The first layers 42a, 42b and 42c may include a first layer 42a formed on the first impurity regions IR1 exposed by the first openings 33a, a first layer 42b formed on the interlayer insulating layer 30 of the first device region A, and a first layer 42c formed on the first mask pattern 36. In particular, the first layers 42a, 42b and 42c may be formed on the regions other than sidewalls of the first openings 33a and a sidewall of the first mask pattern 36. The first layer 42a formed on the first impurity regions IR1 may be filled with the first recesses Ra.

The first layers 42a, 42b and 42c may be a first semiconductor source layer. For example, the first layers 42a, 42b and 42c may include at least one of a silicon material and a germanium material. For example, the first layers 42a, 42b and 42c may include at least one of a silicon layer, a germanium layer and a silicon-germanium layer. The first layers 42a, 42b and 42c may be formed in an amorphous structure.

Before the first layers 42a, 42b and 42c are formed, a first semiconductor material which is the same as the first layers 42a, 42b and 42c may be implanted into the first impurity regions IR1 exposed by the first openings 33a. As above, the regions in which the semiconductor material is implanted into the first impurity regions IR1 may be defined as first buffer regions HD1. The first buffer regions HD1 may be formed during the first vertical deposition process 39. In particular, the first vertical deposition process 39 may include implanting the first semiconductor material into the first impurity regions IR1 to form the first buffer regions HD1, and forming the first layers 42a, 42b and 42c on the first buffer regions HD1. The first semiconductor material may include at least one of a silicon material and a germanium material.

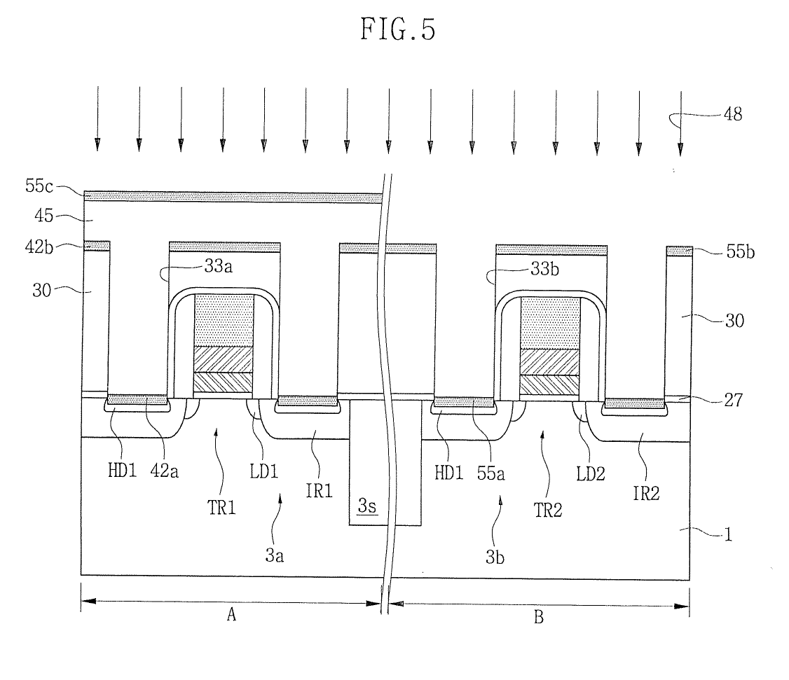

Referring, to FIGS. 1 and 5, a lift-off process may be used, so that the first mask pattern 36 and the first layer 42c on the first mask pattern 36 may be removed. For example, while the first mask pattern 36 is removed using wet etching, the first layer 42c on the first mask pattern 36 may be removed as well.

A second mask pattern 45 covering the semiconductor substrate of the first device region A and exposing the semiconductor substrate of the second device region B may be formed. The second mask pattern 45 may be a photoresist material.

A second vertical deposition process 48 may be performed on the semiconductor substrate having the second mask pattern 45, so that second layers 55a, 55b and 55c may be formed on the semiconductor substrate having the second mask pattern 45 (S140). Thus, the second layers 55a, 55b and 55c may include a second layer 55a formed on the second impurity regions IR2 exposed by the second openings 33b, a second layer 55b formed on the interlayer insulating, layer 30 of the second device region B, and a second layer 55c formed on the second mask pattern 45. In particular, the second layers 55a, 55b and 55c may be formed on regions other than sidewalls of the second openings 33b and a sidewall of the second mask pattern 45. The second layer 55a formed on the second impurity regions IR2 may be filled with the second recesses Rb. Since the second vertical deposition process 48 is performed in a similar manner to the first vertical deposition process (39 of FIG. 4), the detailed description thereof will be omitted.

The second layers 55a, 55b and 55c may be doped using an in-situ doping process to have the same conductivity type as the second impurity regions IR2. In some embodiments, after the second layers 55a, 55b and 55c are formed of a second undoped amorphous layer, second impurity ions having the same conductivity type as the second impurity regions IR2 may be implanted into the second undoped amorphous layer.

The second layers 55a, 55b and 55c may be a second semiconductor source layer. For example, the second layers 55a, 55b and 55c may include at least one of a silicon material and a germanium material. For example, the second layers 55a, 55b and 55c may include at least one of a silicon layer, and a germanium layer and a silicon-germanium layer. The second layers 55a, 55b and 55c may be in an amorphous structure.

Before the second layers 55a, 55b and 55c are formed, a second semiconductor material which is the same as the second layers 55a, 55b and 55c may be implanted into the second impurity regions IR2 exposed by the second openings 33b. As above, the regions in which the second semiconductor material is implanted into the second impurity regions IR2 may be defined as second buffer regions HD2. The second buffer regions HD2 may be formed during the second vertical deposition process 48. In particular, the second vertical deposition process 48 may include implanting the second semiconductor material into the second impurity regions IR2 to form the second buffer regions HD2, and forming the second layers 55a, Sib and 55c on the second buffer regions HD2. The second semiconductor material may include at least one of a silicon material and a germanium material.

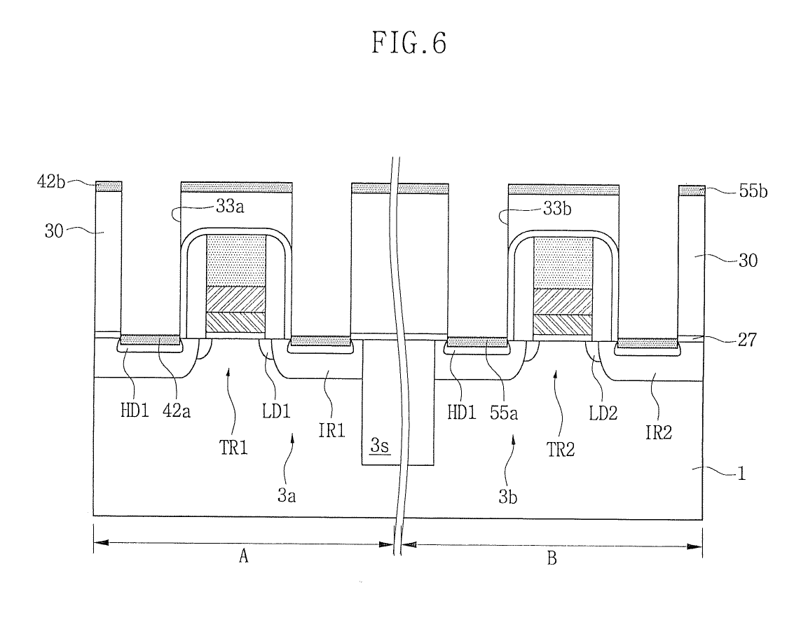

Referring, to FIGS. 1 and 6, a lift-off process may be used, so that the second mask pattern 45 and the second layer 55c on the second mask pattern 45 may be removed. For example, while the second mask pattern 45 is removed using wet etching, the second layer 55c on the second mask pattern 45 may be removed as well. Thus, the first layers 42a and 42b containing the first impurities having the same conductivity type as the second impurity regions IR2 may be formed in the first device region A, and the second layers 55a and 55b containing impurities having the same conductivity type as the second impurity regions IR2 may be formed in the second device region B.

In further embodiments, forming the first and second layers 42a, 42b, 55a, and 55b may include forming an amorphous layer containing a silicon material and/or a germanium material on the semiconductor substrate having the first and second openings 33a and 33b, performing a first ion implantation process such that an amorphous layer in the first device region A has the same conductivity type as the first impurity regions IR1, and performing a second ion implantation process such that an amorphous layer in the second device region B has the same conductivity type as the second impurity regions IR2. As a result, results substantially the same as the first and second layers 42a, 42b, 55a and 55b may be formed.

An annealing process may be performed (S150) on the semiconductor substrate having the first and second layers 42a, 42b, 55a, and 55b, so that impurities implanted into the first and second layers 42a, 42b, 55a and 55b may be activated, and the first and second layers 42a, 42b, 55a and 55b in an amorphous structure may be crystallized.

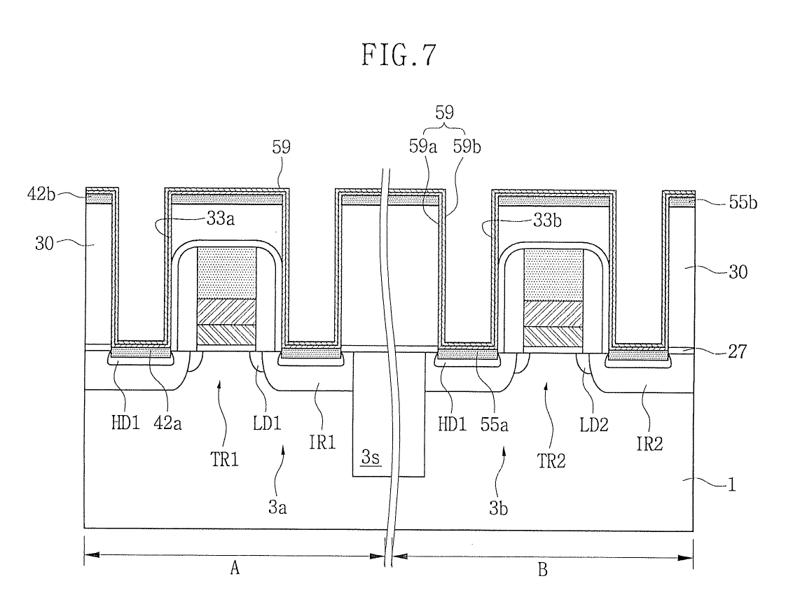

Referring to FIGS. 1 and 7, a third layer 59 may be formed on the surface of the semiconductor substrate having the first and second layers 42a, 42b, 55a and 55b (S160). The third layer 59 may be defined as a metal source layer. For example, the third layer 59 may include a metal layer 59a and a barrier layer 59b, which are stacked. For example, the metal layer 59a of the third layer 59 may be a metal layer, such as a Ti layer, a Co layer, a Ta layer and/or a Ni layer, and the barrier layer 59b of the third layer 59 may be a metal nitride layer, such as a TiN layer and/or a TaN layer.

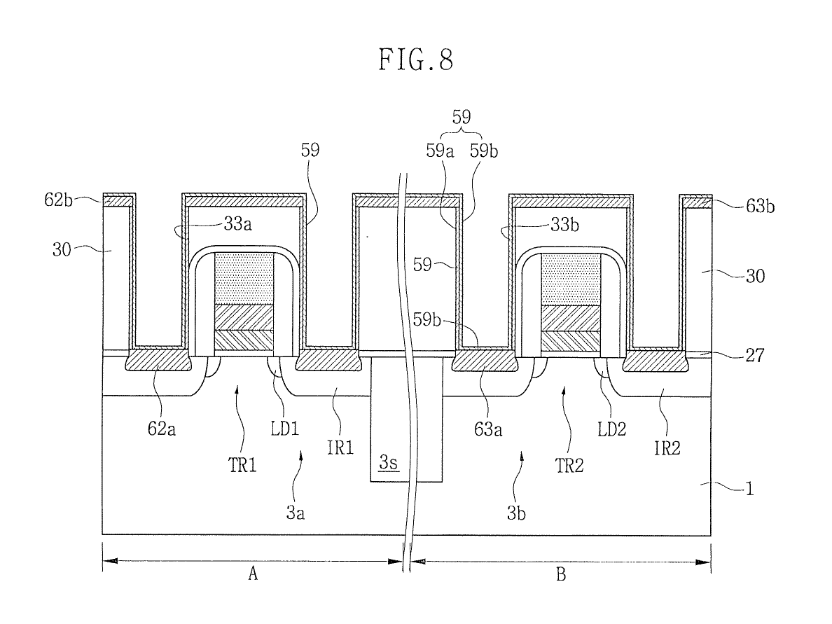

Referring to FIGS. 1 and 8, a silicide annealing process may be performed on the semiconductor substrate having the third layer 59, so that a first metal-semiconductor compound region 62a may be formed on the first impurity regions IR1, a second metal-semiconductor compound region 62b may be formed on the interlayer insulating layer 30 of the first device region A, a third metal-semiconductor compound region 63a may be formed on the second impurity regions IR2, and a fourth metal-semiconductor compound region 63b may be formed on the interlayer insulating layer 30 of the second device region B (S170).

The first metal-semiconductor compound region 62a may use the metal layer 59a of the third layer 59 as a metal source, and may be a metal-semiconductor compound, i.e., silicide that is formed using a silicon material and/or a germanium material of the first layer (42a of FIG. 7), the first buffer regions (HD1 of FIG. 7) and the first impurity regions IR1 as a semiconductor source. The first layer (42a of FIG. 7) providing a semiconductor source to the first metal-semiconductor compound region 62a may keep a physical distance between p-n junctions of the first transistor TR1 and the first metal-semiconductor compound region 62a from being close. The first buffer regions HD1 may keep a physical distance between p-n junctions of the first transistor TR1 and the first metal-semiconductor compound region 62a from being close. Thus, junction leakage of the first transistor TR1 may be reduced or suppressed. Further, a transistor TR1 having a source/drain region IR1 of a shallow region may be formed. The p-n junctions of the first transistor TR1 may be defined as a junction between the first impurity regions IR1 defined as source/drain regions and an active region 3a between the first impurity regions IR1, i.e., a junction between channel regions may be defined. For example, when the first transistor TR1 is an NMOS transistor, the p-n junctions may be defined as a junction between the n-type first impurity regions IR 1 and the p-type first active region 3a.

The second metal-semiconductor compound region 62b may be a silicide layer formed by a reaction of the first layer (42b of FIG. 7) on the interlayer insulating layer 30 of the first device region A with the metal layer 59a of the third layer 59. Thus, since the second metal-semiconductor compound region 62b lacks a semiconductor source compared to the first metal-semiconductor compound region 62a, it may be formed thinner than the first metal-semiconductor compound region 62a. However, the second metal-semiconductor compound region 62b may not be necessarily formed thinner than the first metal-semiconductor compound region 62a. For example, when thicknesses of the first layers 42a and 42b are sufficiently thick, i.e., a semiconductor source provided from the first layers 42a and 42b is sufficient, the first metal-semiconductor compound region 62a may have substantially the same thickness as the second metal-semiconductor compound region 62b.

Like the first metal-semiconductor compound region 62a, the third metal-semiconductor compound region 63a may be a silicide layer, in which the metal layer 59a is used as a metal source, and a silicon material and a germanium material of the second layer (55a of FIG. 7), the second buffer regions (HD2 of FIG. 7), and the second impurity regions IR2 are used as semiconductor sources. The fourth metal-semiconductor compound region 63b may be a silicide layer formed by a reaction of the second layer (55b of FIG. 7) on the interlayer insulating layer 30 of the second device region B with the metal layer 59a of the third layer 59.

During the silicide annealing process, the metal layer 59a of the third layer 59 may be used to provide a metal material constituting a metal-semiconductor compound region, and the barrier layer 59b of the third layer 59 may function to prevent oxidation of the metal layer 59a.

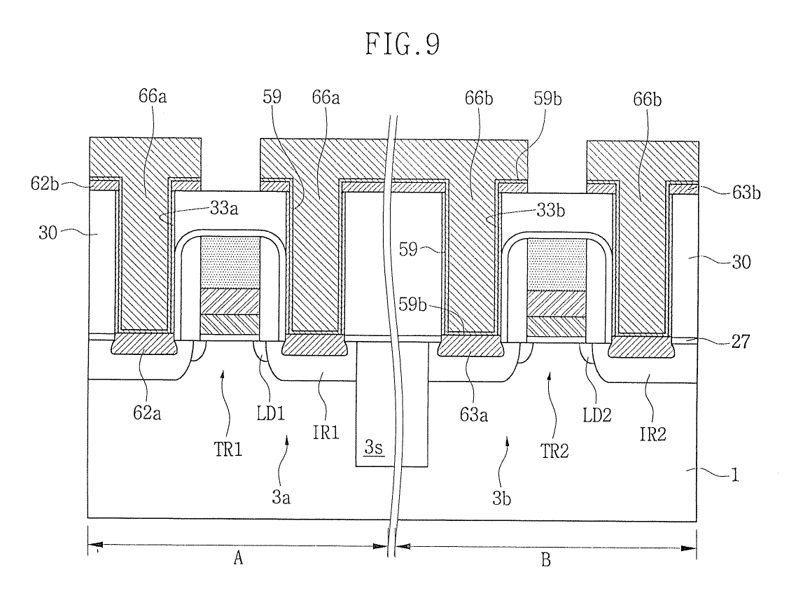

Referring to FIGS. 1 and 9, a conductive layer may be formed on the semiconductor substrate having the first to fourth metal-semiconductor compound regions 62a, 62b, 63a, and 63b. For example, the conductive layer may be a metal layer, such as a tungsten layer or a copper layer. The barrier layer 59b of the third layer 59 may prevent a process gas for forming the conductive layer and/or a metal material constituting the conductive layer from infiltrating into the semiconductor substrate, e.g., the interlayer insulating layer 30.

The conductive layer may be patterned using photolithography to form first interconnections 66a filling the first openings 33a and electrically connected to the first impurity regions IR1, respectively, and form second interconnections 66b filling the second

openings 33b and electrically connected to the second impurity regions IR2. respectively. In some embodiments, the conductive layer may be planarized until the interlayer insulating layer 30 is exposed.

According to some embodiments of the inventive subject matter, a metal-semiconductor compound region is formed using a semiconductor source layer, such as a silicon layer formed on a source/drain region of a transistor, so that a transistor, in which contact resistance of the source/drain regions of the transistor may be improved and junction depth of the source/drain regions may be reduce, can be provided.

While some embodiments have been disclosed herein, it should be understood that other variations may be possible. Such variations are not to be regarded as a departure from the spirit and scope of some embodiments of the present application, and all such modifications as would be obvious to one skilled in the art are intended to be included within the scope of the following claims.

What is claimed is:

1. A method of fabricating a semiconductor device, the method comprising:
forming a transistor on and/or in a semiconductor substrate, wherein the transistor comprises a source/drain region and a gate pattern disposed on a channel region adjacent the source/drain region;
forming an insulating layer on the transistor;
patterning the insulating layer to expose the source/drain region;
forming a semiconductor source layer on the exposed source/drain region and on an adjacent portion of the insulating layer;
forming a metal source layer on the semiconductor source layer; and
annealing to form a first metal-semiconductor compound region on the source/drain region and a second metal-semiconductor compound region on the adjacent portion of the insulating layer.

2. The method of claim 1, wherein the first metal-semiconductor compound region comprises a semiconductor material from the semiconductor source layer, a semiconductor material from the source/drain region and a metal material from the metal source layer, and wherein the second metal-semiconductor compound region comprises a semiconductor material from the first semiconductor source layer and the metal material from the metal source layer.

3. The method of claim 1, wherein forming the semiconductor source layer is preceded by implanting a semiconductor material into the source/drain region and forming a buffer region on the implanted source/drain region.

4. The method of claim 3, wherein the first metal-semiconductor compound region comprises a semiconductor material from the semiconductor source layer, a semiconductor material from the source/drain regions and the semiconductor material implanted into the buffer region.

5. The method of claim 1, wherein forming the semiconductor source layer is preceded by forming a recess in the exposed source/drain region and wherein forming the semiconductor source layer comprises filling the recess with the semiconductor source layer.

6. The method of claim 1, wherein the first metal-semiconductor compound region is thicker than the second metal-semiconductor compound region.

7. The method of claim 1:
wherein forming the transistor comprises forming spaced apart first and second transistors on and/or in the semiconductor substrate, wherein the first transistor comprises a first source/drain region and a first gate pattern disposed on a first channel region adjacent the first source/drain region and wherein the second transistor comprises a second source/drain region and a second gate pattern disposed on a second channel region adjacent the second source/drain region:
wherein forming the insulating layer comprises forming the insulating layer on the first and second transistors:
wherein patterning the insulating layer comprises patterning the insulating layer to expose the first source/drain region and the second source/drain region;
wherein forming the semiconductor source layer comprises:
forming a mask layer on the exposed second source/drain region:
forming a first semiconductor source layer on the exposed first source/drain regions and on a first portion of the insulating layer adjacent the first source/drain region;
removing the mask layer to expose the second source/drain region; and
forming a second semiconductor source layer on the exposed second source/drain region and on second portion of the insulating layer adjacent the second source/drain region; and
wherein annealing comprises annealing to form the first metal-semiconductor compound region on the first source/drain region, the second metal-semiconductor compound region on the first adjacent portion of the insulating layer, a third metal-semiconductor compound region on the second source/drain region and a fourth metal-semiconductor compound region on the second adjacent portion of the insulating layer.

8. The method of claim 7, wherein the first and second source/drain regions have different conductivity types, wherein the first semiconductor source layer comprises an amorphous structure having the same conductivity type as the first source/drain region, and wherein the second semiconductor source layer comprises an amorphous structure having the same conductivity type as the second source/drain region.

9. The method of claim 8, further comprising performing an annealing process for crystallizing the first and second semiconductor source layers after the first and second semiconductor source layers are formed.

10. The method of claim 1, wherein the metal source layer comprises a metal layer and a metal nitride barrier layer.
